(19) United States
(12) Patent Application Publication
(10) Pub. No.: US 2026/0068211 A1
(43) Pub. Date: Mar. 5, 2026

(54) SEMICONDUCTOR DEVICE AND METHOD OF MANUFACTURING THE SEMICONDUCTOR DEVICE

(71) Applicant: Samsung Electronics Co., Ltd., Suwon-si (KR)

(72) Inventors: Eunji YANG, Suwon-si (KR); Changhyun KIM, Suwon-si (KR)

(73) Assignee: Samsung Electronics Co., Ltd., Suwon-si (KR)

(21) Appl. No.: 19/240,727

(22) Filed: Jun. 17, 2025

(30) Foreign Application Priority Data
Aug. 30, 2024 (KR) 10-2024-0117885

(51) Int. Cl. H10D 30/00; H10D 30/01; H10D 30/47; H10D 62/10; H10D 62/80; H10D 64/27; H10D 64/66; H10D 64/68

(52) U.S. Cl. CPC H10D 30/503; H10D 30/017; H10D 30/0191; H10D 30/481; H10D 62/102; H10D 62/875; H10D 62/883; H10D 64/514; H10D 64/518; H10D 64/667; H10D 64/691

(57) ABSTRACT

A semiconductor device may include a first gate electrode and a second gate electrode spaced apart from each other on a substrate, a first channel layer on one side of the first gate electrode, a second channel layer on one side of the second gate electrode, and a third gate electrode connecting the first gate electrode and the second gate electrode to each other. The first channel layer and the second channel layer may extend in a first direction and the first direction may be perpendicular to the substrate.

### CROSS-REFERENCE TO RELATED APPLICATION

This application is based on and claims priority under 35 U.S.C § 119 to Korean Patent Application No. 10-2024-0117885, filed on Aug. 30, 2024, in the Korean Intellectual Property Office, the disclosure of which is incorporated by reference herein in its entirety.

### BACKGROUND

### 1. Field

The disclosure relates to a semiconductor device and/or a method of manufacturing the semiconductor device.

### 2. Description of the Related Art

As semiconductor processes become more miniaturized, transistor sizes decrease, and the area where a gate electrode and a channel meet becomes smaller, and issues caused by short-channel effects may occur. The gate-all-around (GAA) structure is attracting attention as a way to reduce short-channel effects and improve gate control. Due to their excellent scaling properties, transition metal dichalcogenide (TMD) materials may be advantageous for implementing multi-bridge channel field-effect transistors (MBCFETs) with GAA structures.

However, it may be difficult to apply existing silicon-based processes to TMD materials, and damage to TMD materials may occur during the processes. Therefore, process development may be needed to manufacture TMD MBCFETs while maintaining the quality of TMD materials.

### SUMMARY

Provided is a semiconductor device with a GAA structure and/or a method of manufacturing the semiconductor device.

Additional aspects will be set forth in part in the description which follows and, in part, will be apparent from the description, or may be learned by practice of the presented embodiments of the disclosure.

According to an example embodiment of the disclosure, a semiconductor device may include a first gate electrode and a second gate electrode spaced apart from each other on a substrate, a first channel layer on one side of the first gate electrode, a second channel layer on one side of the second gate electrode, and a third gate electrode connecting the first gate electrode and the second gate electrode. The first channel layer and the second channel layer may extend in a first direction and the first direction may be perpendicular to the substrate.

In some embodiments, the first channel layer may be surrounded by the first gate electrode and the third gate electrode.

In some embodiments, the second channel layer may be surrounded by the second gate electrode and the third gate electrode.

In some embodiments, a part of the first channel layer and a part of the second channel layer may extend in a second direction and the second direction may be perpendicular to the first direction.

In some embodiments, the first gate electrode, the second gate electrode, and the third gate electrode may include TiN.

In some embodiments, the first channel layer and the second channel layer may each independently include a transition metal dichalcogenide (TMD) or an oxide semiconductor.

In some embodiments, at least one of the first channel layer and the second channel layer include the TMD, and the TMD may include MoS₂, WSe₂, MoSe₂, or WS₂.

In some embodiments, at least one of the first channel layer and the second channel layer include the oxide semiconductor, and the oxide semiconductor may include indium-gallium-zinc oxide IGZO or indium tin oxide (ITO).

In some embodiments, the semiconductor device may further include a gate insulating layer surrounding the first channel layer and the second channel layer.

In some embodiments, the gate insulating layer may include a high-k material.

In some embodiments, the gate insulating layer may include at least one of aluminum oxide, hafnium oxide, zirconium oxide, or lanthanum oxide.

In some embodiments, the first channel layer and the second channel layer may be symmetric with respect to the third gate electrode.

In some embodiments, the first channel layer and the second channel layer may not be symmetric with respect to the third gate electrode.

According to an example embodiment of the disclosure, a semiconductor device may include a plurality of first gate electrodes spaced apart from each other in a first direction on a surface of a substrate, the first direction being perpendicular to the surface of the substrate; a plurality of second gate electrodes on the surface of the substrate and spaced apart from each other in the first direction; a plurality of first channel layers on one side of the plurality of first gate electrodes, respectively; a plurality of second channel layers on one side of the plurality of second gate electrodes, respectively; a third gate electrode connecting the plurality of first gate electrodes and the plurality of second gate electrodes to each other; and a source electrode and a drain electrode spaced apart in a second direction on the substrate, the second direction being perpendicular to the first direction. The plurality of first channel layers and the plurality of second channel layers may extend in the first direction.

In some embodiments, the plurality of first gate electrodes and the plurality of second gate electrodes may be spaced apart from each other in the second direction.

In some embodiments, the plurality of first channel layers may be surrounded by the plurality of first gate electrodes and the third gate electrode.

In some embodiments, the plurality of second channel layers may be surrounded by the plurality of second gate electrodes and the third gate electrode.

According to an example embodiment of the disclosure, a method of manufacturing a semiconductor device may include forming a plurality of gate electrodes spaced apart from each other in a first direction on a substrate, the first direction being perpendicular to the substrate; forming a channel layer surrounding each of the plurality of gate electrodes; etching a part of the plurality of gate electrodes to form a first gate electrode and a second gate electrode, and etching a part of the channel layer to form a first channel layer and a second channel layer; forming a source electrode and a drain electrode spaced apart from each other on the substrate; and forming a third gate electrode surrounding the first channel layer and the second channel layer. The first channel layer and the second channel layer may extend in the first direction.

In some embodiments, the first channel layer may be surrounded the first gate electrode and the third gate electrode.

In some embodiments, the second channel layer may be surrounded by the second gate electrode and the third gate electrode.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view illustrating a semiconductor device according to an embodiment,

FIG. 2 is a cross-sectional view taken along line A-A′ of FIG. 1,

FIG. 3 is a cross-sectional view taken along line B-B′ of FIG. 1,

FIG. 4 is a plan view of the semiconductor device of FIG. 1,

FIGS. 5A to 5L are diagrams illustrating a method of manufacturing a semiconductor device according to an embodiment,

FIGS. 6A to 6G are plan views of the semiconductor device corresponding to FIGS. 5F to 5L,

FIG. 7 is a schematic block diagram of a display driver integrated circuit DDI including a field-effect transistor and a display device including the DDI, according to an embodiment,

FIG. 8 is a block diagram of an electronic system including a semiconductor device according to an embodiment,

FIG. 9 is a block diagram of an electronic system including a semiconductor device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

Hereinafter, the semiconductor device and the method of manufacturing the semiconductor device according to various embodiments are described in detail with reference to the attached drawings. In the drawings below, the same reference numerals refer to the same components, and the size of each component in the drawings may be exaggerated for clarity and convenience of explanation. In addition, the embodiments described below are merely examples, and various modifications are possible from these embodiments.

Hereinafter, terms “upper” or “on” may refer to something directly on top or indirectly placed above through non-contact. Singular expressions include plural expressions unless the context clearly indicates otherwise. Additionally, when an element is said to “include” a component, this does not mean that it excludes other components, but rather that it may include other components, unless otherwise specifically stated.

The use of the term “above” and similar referential terms may refer to both the singular and the plural. Unless the operations of a method are explicitly described in a specific order or to the contrary, these operations may be performed in any suitable order and are not necessarily limited to the order described.

The connections or lack of connections between the lines depicted in the drawings are merely illustrative of functional connections and/or physical or circuit connections, and may be represented in an actual device as alternative or additional various functional connections, physical connections, or circuit connections.

Any use of examples or example terms is intended merely to elaborate technical concepts in detail and is not intended to limit the scope of the disclosure unless otherwise defined by the claims.

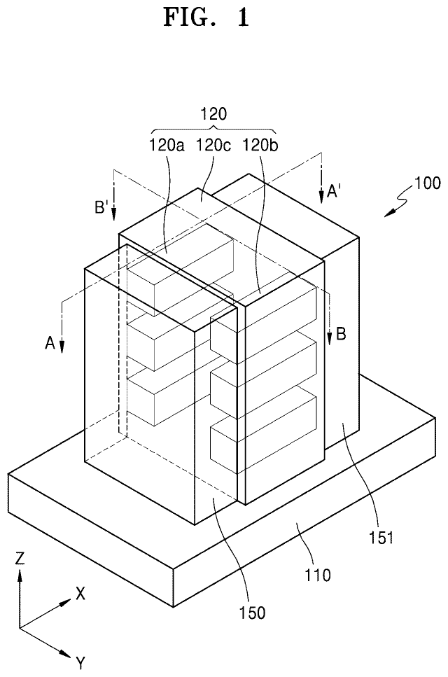

FIG. 1 is a perspective view illustrating a semiconductor device according to an embodiment.

Referring to FIG. 1, a semiconductor device 100 may include a source electrode 150 and a drain electrode 151 provided on a substrate 110 and spaced apart in a direction parallel to the surface of the substrate 110, a plurality of first gate electrodes 120a and a plurality of second gate electrodes 120b connecting the source electrode 150 and the drain electrode 151, and a third gate electrode 120c connecting the plurality of first gate electrodes 120a and the plurality of second gate electrodes 120b.

The substrate 110 may be an insulating substrate, or may be a semiconductor substrate with an insulating layer formed on the surface. For example, the substrate 110 may include silicon (Si), such as single crystal silicon, polycrystalline silicon, or amorphous silicon. The substrate 110 may include a group IV semiconductor such as germanium (Ge), a group IV-IV compound semiconductor such as silicon germanium (SiGe) or silicon carbide (SiC), or a group III-V compound semiconductor such as gallium arsenide (GaAs), indium arsenide (InAs), or indium phosphide (InP). The substrate 110 may be based on a silicon bulk substrate or may be based on a Silicon On Insulator (SOI) substrate. The substrate 110 is not limited to a bulk or SOI substrate, but may also be a substrate based on an epitaxial wafer, a polished wafer, an annealed wafer, and the like.

The substrate 110 may include a conductive region, such as a well doped with impurities, or various structures doped with impurities. Additionally, the substrate 110 may be configured as a p-type substrate or an n-type substrate depending on the type of impurity ion being doped.

The source electrode 150 and the drain electrode 151 may include, but are not limited to, a metal material having excellent electrical conductivity, such as Ag, Au, Pt, or Cu.

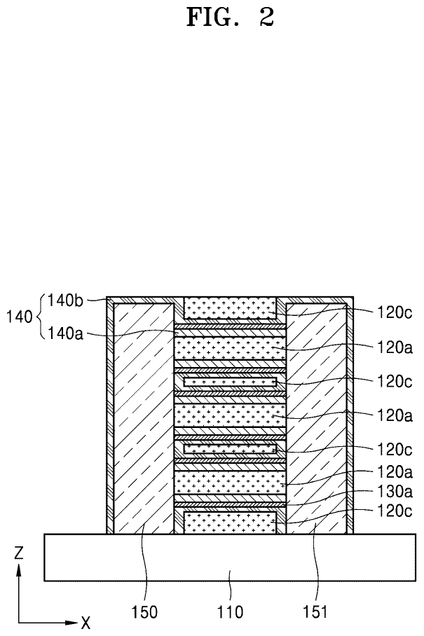

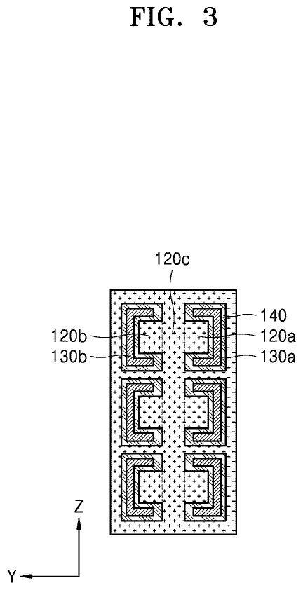

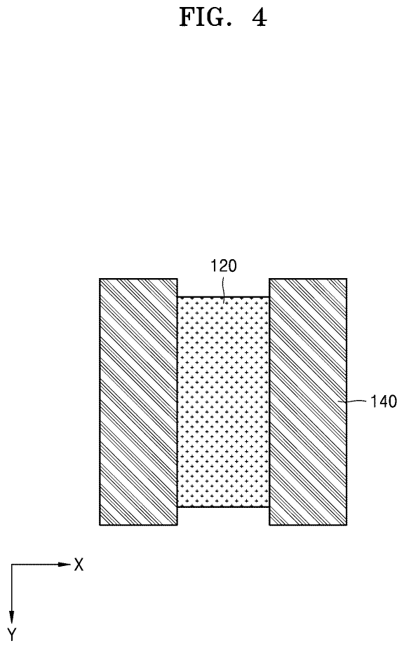

FIG. 2 is a cross-sectional view taken along line A-A′ of FIG. 1, FIG. 3 is a cross-sectional view taken along line B-B′ of FIG. 1, and FIG. 4 is a plan view of the semiconductor device of FIG. 1.

Referring to FIGS. 2 to 4, the semiconductor device 100 may include a plurality of first gate electrodes 120a and a plurality of second gate electrodes 120b spaced apart from each other on a substrate 110, a first channel layer 130a provided to surround one side of the first gate electrode 120a, a second channel layer 130b provided to surround one side of the second gate electrode 120b, and a third gate electrode 120c connecting the first gate electrodes 120a and the second gate electrodes 120b.

Each of the plurality of first gate electrodes 120a may be spaced apart in a direction perpendicular to the surface of the substrate 110. Each of the plurality of second gate electrodes 120b may be spaced apart in a direction perpendicular to the surface of the substrate 110.

The first channel layer 130a may be provided to be surrounded by a gate electrode 120. The first channel layer 130a may be provided to be surrounded by a first gate electrode 120a and a third gate electrode 120c.

The first channel layer 130a may include, for example, Transition Metal Dichalcogenide (TMD). TMD may be represented, for example, by Formula MX₂, where M represents a transition metal and X represents a chalcogen element. For example, M may be Mo, W, Nb, V, Ta, Ti, Zr, Hf, Tc, Re, etc., and X may be S, Se, Te, etc. So, for example, TMD may include MoS₂, WSe₂, MoSe₂, or WS₂.

The first channel layer 130a may include, for example, an oxide semiconductor. The oxide semiconductor may include, for example, IGZO or ITO.

The second channel layer 130b may be provided to be surrounded by a gate electrode 120. The second channel layer 130b may be provided to be surrounded by a second gate electrode 120b and a third gate electrode 120c.

The second channel layer 130b may include, for example, Transition Metal Dichalcogenide (TMD). TMD may be represented, for example, as Formula MX₂, where M represents a transition metal and X represents a chalcogen element. For example, M may be Mo, W, Nb, V, Ta, Ti, Zr, Hf, Tc, Re, etc., and X may be S, Se, Te, etc. TMD may include, for example, MoS₂, WSe₂, MoSe₂, or WS₂. However, it is not limited to these and other materials may be used as TMD materials.

The second channel layer 130b may include, for example, an oxide semiconductor. The oxide semiconductor may include, for example, Indium-Gallium-Zinc Oxide (IGZO) or Indium Tin Oxide (ITO).

The first channel layer 130a and the second channel layer 130b may extend in a direction perpendicular to the surface of the substrate 110. The first channel layer 130a and the second channel layer 130b may have an I-shaped structure in the YZ plane. Some parts of the first channel layer 130a and the second channel layer 130b may extend in a direction perpendicular to the surface of the substrate 110, while other parts may extend in a direction parallel to the surface of the substrate 110. The first channel layer 130a and the second channel layer 130b may have a C-shaped structure in the YZ plane.

As shown in FIG. 3, the first channel layer 130a and the second channel layer 130b may have a symmetric structure with respect to the third gate electrode 130c. However, they are not limited thereto, and the first channel layer 130a and the second channel layer 130b may not have a symmetric structure with respect to the third gate electrode 120c. For example, the first channel layer 130a may have an I-shaped structure in the YZ plane, and the second channel layer 130b may have a C-shaped structure in the YZ plane.

A gate insulating layer 140 may be provided to surround the first channel layer 130a and the second channel layer 130b. The gate insulating layer 140 may be provided to surround all sides of the first channel layer 130a and the second channel layer 130b. All sides of the gate insulating layer 140 may be provided to be surrounded by the gate electrode 120.

The gate insulating layer 140 insulates between the first channel layer 130a and the gate electrode 120, thereby limiting and/or suppressing leakage current. The gate insulating layer 140 insulates between the second channel layer 130b and the gate electrode 120, thereby limiting and/or suppressing leakage current.

The gate insulating layer 140 may include a high-k material. For example, the gate insulating layer 140 may include aluminum oxide, hafnium oxide, zirconium oxide, zirconium hafnium oxide, or lanthanum oxide. However, it is not limited to these.

The gate electrode 120 may include the first gate electrode 120a, the second gate electrode 120b, and the third gate electrode 120c. The first gate electrode 120a, the second gate electrode 120b, and the third gate electrode 120c may be made of the same material. The first gate electrode 120a, the second gate electrode 120b, and the third gate electrode 120c may include, for example, TiN.

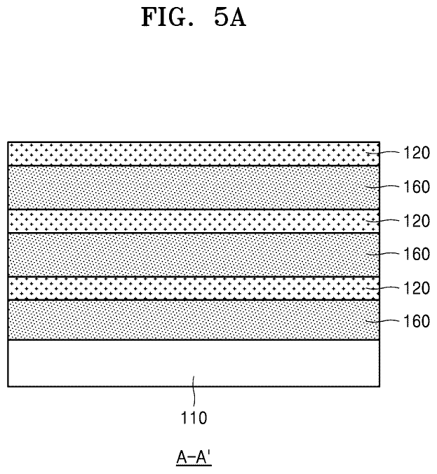

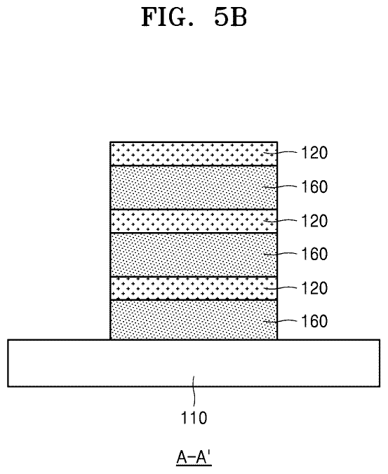

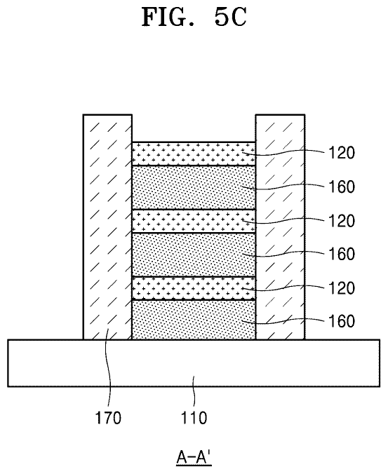

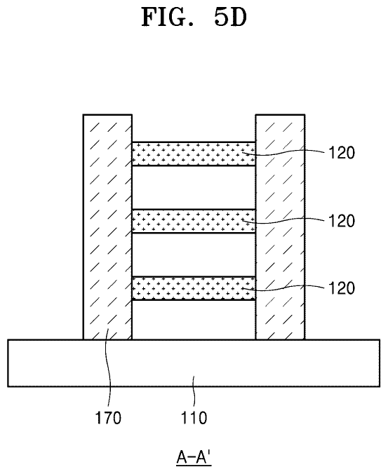

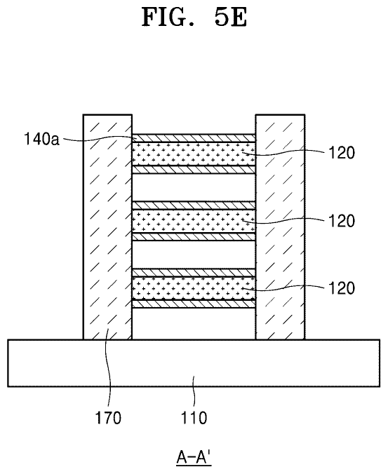

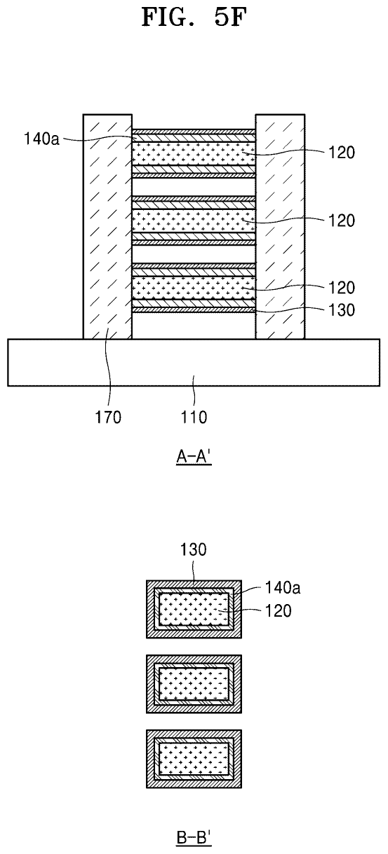

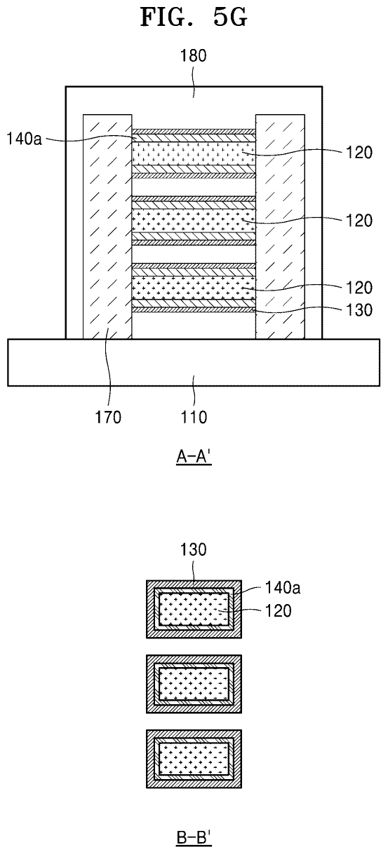

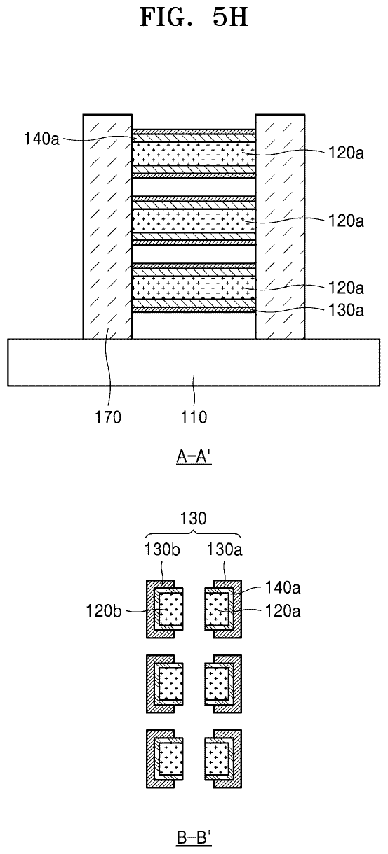

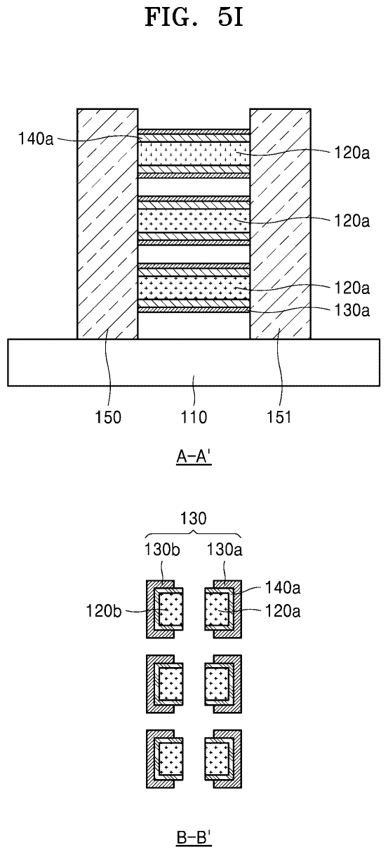

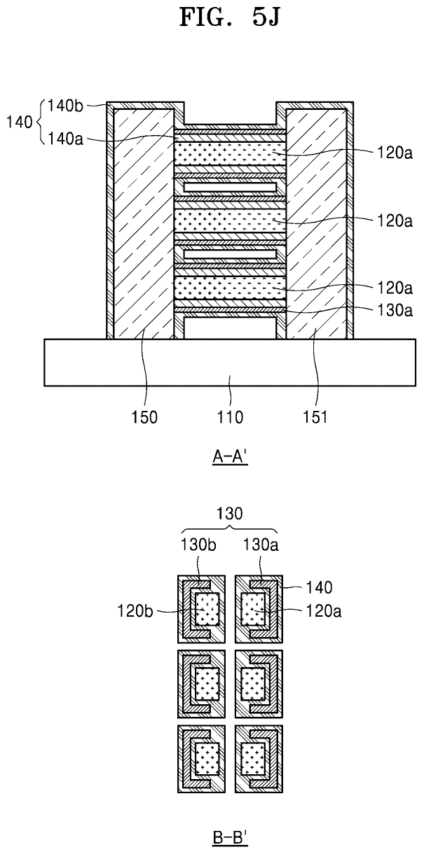

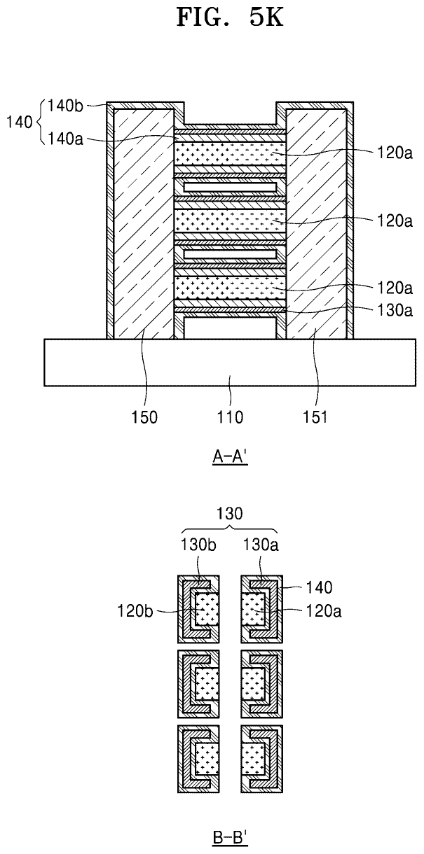

FIGS. 5A to 5L are drawings illustrating a method of manufacturing a semiconductor device according to an embodiment.

The method of manufacturing a semiconductor device is described by showing the manufacturing process operations together with the cross-sectional views along lines A-A′ and B-B′ of FIG. 1.

Referring to FIG. 5A, a sacrificial layer 160 and a gate electrode 120 may be alternately stacked on a substrate 110 in a direction perpendicular to the substrate 110 to form a stacked structure. The substrate 110 may be the substrate 110 described in FIG. 1. The sacrificial layer 160 and the gate electrode 120 may be composed of materials that can be selectively removed depending on the etching gas or etching liquid. The sacrificial layer 160 may include, for example, an inorganic material such as SiO₂, Al₂O₃, Si₃N₄, poly-Si, SiGe, or an organic material such as polymethyl methacrylate PMMA. The gate electrode 120 may include, for example, TiN.

Referring to FIGS. 5B and 5C, both sides of the stacked structure of the sacrificial layer 160 and the gate electrode 120 are etched to pattern the stacked structure. Then, a support 170 is provided on both sides of the sacrificial layer 160 and the gate electrode 120. The support 170 may include an insulating material. The support 170 may include, for example, silicon nitride.

Referring to FIG. 5D, the sacrificial layer 160 may be removed. The support 170 may serve to support the plurality of gate electrodes 120 when the sacrificial layer 160 is etched. As the sacrificial layer 160 is removed, the plurality of gate electrodes 120 may be spaced apart in a direction perpendicular to the substrate 110.

Referring to FIG. 5E, a first gate insulating layer 140a may be formed surrounding each of the plurality of gate electrodes 120. The first gate insulating layer 140a may be formed by Chemical Vapor Deposition (CVD), Metal Organic Chemical Vapor Deposition (MOCVD), or Atomic Layer Deposition (ALD) processes.

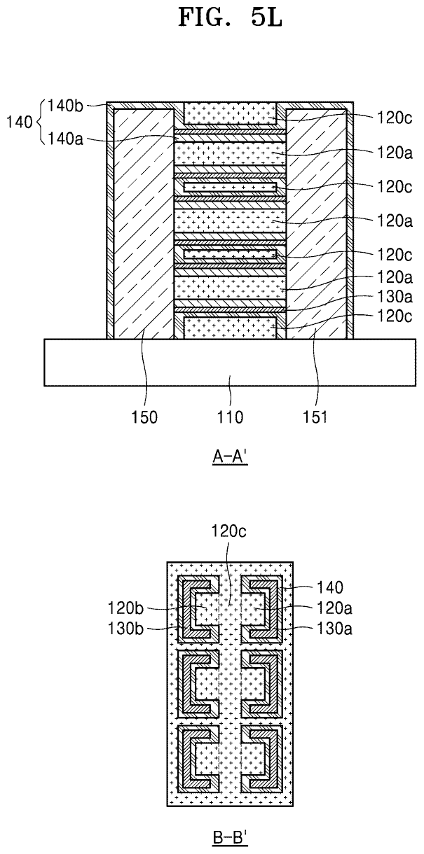

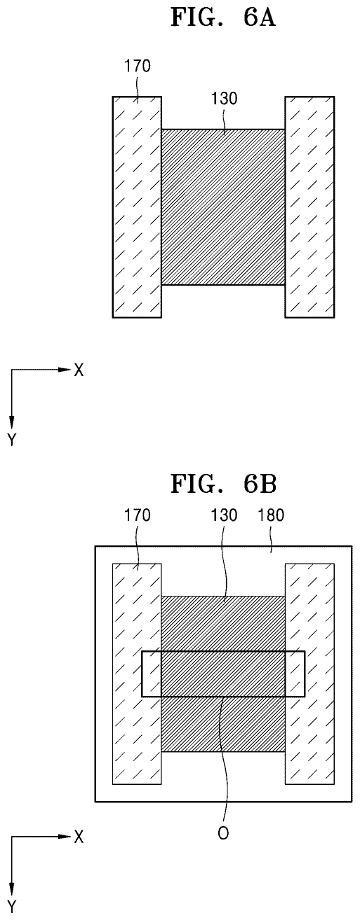

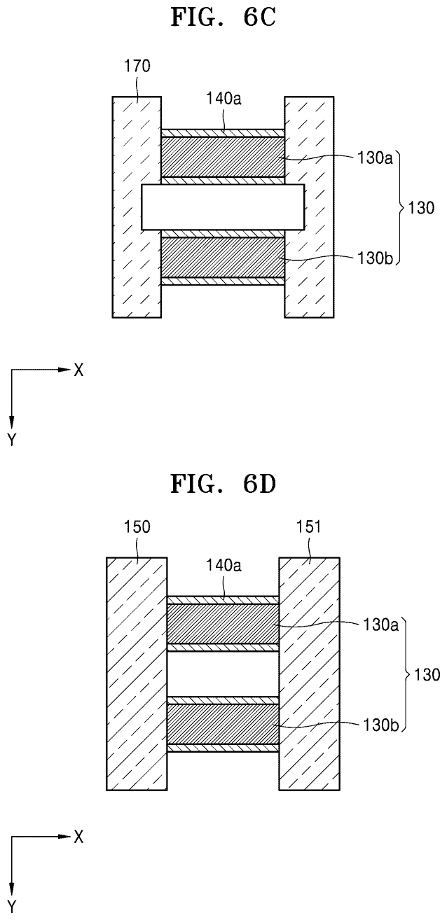

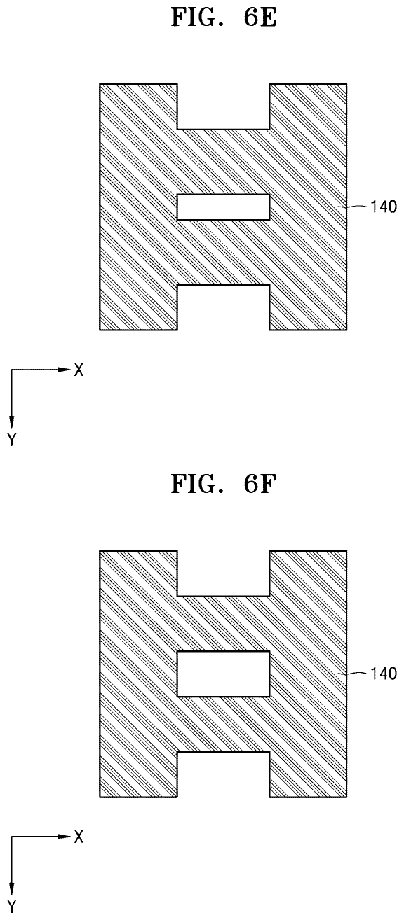

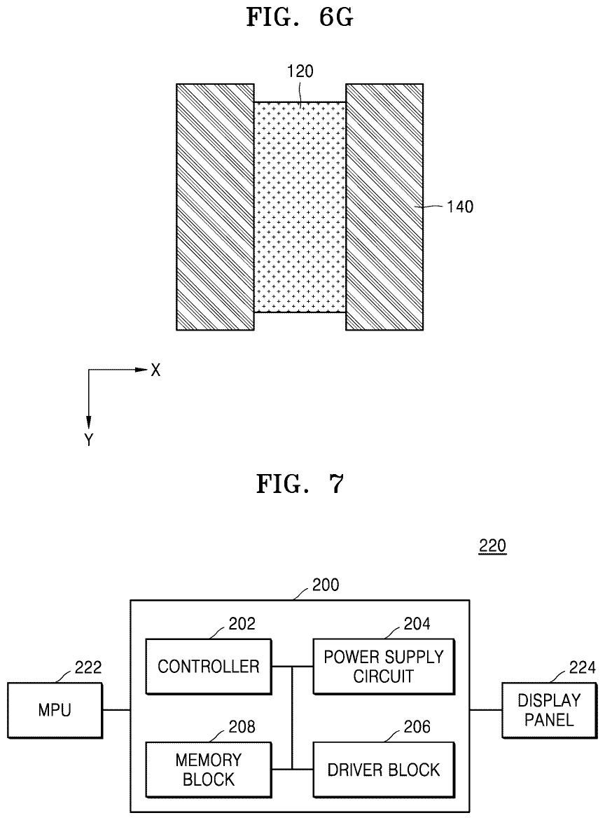

FIGS. 6A to 6G are plan views of semiconductor devices corresponding to FIGS. 5F to 5L, respectively.

When explaining FIGS. 5F to 5L, reference is made to FIGS. 6A to 6G.

Referring to FIGS. 5F and 6A, a channel layer 130 surrounding each of a plurality of gate electrodes 120 may be formed. The channel layer 130 may be formed by CVD, MOCVD or ALD processes. A first gate insulating layer 140a may be provided between the gate electrode 120 and the channel layer 130.

Referring to FIGS. 5G and 6B, a photoresist (PR) 180 may be provided on top of the stacked structure. The PR 180 may include a square-shaped opening O in the center.

Referring to FIGS. 5H and 6C, the center of the stacked structure may be etched through the PR 180 including a square-shaped opening O in the center. At this time, part of the gate electrode 120 may be etched to form a first gate electrode 120a and a second gate electrode 120b, and part of the channel layer 130 may be etched to form a first channel layer 130a and a second channel layer 130b. The first channel layer 130a and the second channel layer 130b may extend in a direction perpendicular to the substrate 110. Additionally, the first gate insulating layer 140a may also be etched. At this time, the etched area of the channel layer 130 may be larger than the etched area of the first gate insulating layer 140a. That is, the first gate insulating layer 140a may be etched so that it becomes visible in the plan view of FIG. 6C.

Referring to FIGS. 5I and 6D, a source electrode 150 and a drain electrode 151 may be formed surrounding each support 170. The source electrode 150 and the drain electrode 151 may include, but are not limited to, highly electrically conductive metal materials such as Ag, Au, Pt, or Cu.

Referring to FIGS. 5J and 6E, a second gate insulating layer 140b surrounding the gate structure may be provided. The second gate insulating layer 140b may be formed by CVD, MOCVD or ALD processes. The plurality of first gate electrodes 120a may be surrounded by the gate insulating layer 140. The plurality of second gate electrodes 120b may be surrounded by the gate insulating layer 140.

Referring to FIGS. 5K and 6F, part of the gate insulating layer 140 may be etched to expose part of the surface of the plurality of first gate electrodes 120a and the plurality of second gate electrodes 120b.

Referring to FIG. 5L and FIG. 6G, a third gate electrode 120c may be formed to surround the first channel layer 130a and the second channel layer 130b. The third gate electrode 120c may be formed to fill the space between the first gate electrode 120a and the second gate electrode 120b. The third gate electrode 120c may be connected to the plurality of first gate electrodes 120a. The third gate electrode 120c may be connected to the plurality of second gate electrodes 120b. Through this, a pair of MBCFETs may be manufactured in which all channel layers 130 may have a GAA structure.

FIG. 7 is a schematic block diagram of a display driver integrated circuit DDI and a display device having the DDI according to an embodiment.

Referring to FIG. 7, the DDI 200 may include a controller 202, a power supply circuit 204, a driver block 206, and a memory block 208. The controller 202 receives and decodes instructions from a main processing unit (MPU) 222, and controls each block of the DDI 200 to implement the operations according to the instructions. The power supply circuit 204 generates a driving voltage in response to the control of the controller 202. The driver block 206 drives a display panel 224 using the driving voltage generated in the power supply circuit 204 in response to the control of the controller 202. The display panel 224 may be a liquid crystal display panel or a plasma display panel. The memory block 208 is a block that temporarily stores commands input to the controller 202 or control signals output from the controller 202, or stores necessary data, and may include a memory such as RAM or ROM. The power supply circuitry 204 and driver block 206 may include semiconductor devices according to the embodiments described above with reference to FIGS. 1 to 4.

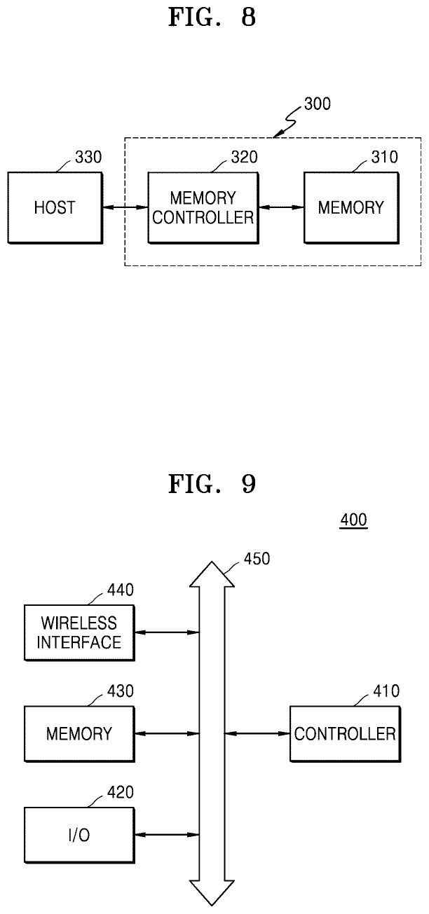

FIG. 8 is a block diagram of an electronic system including a semiconductor device according to an embodiment.

The electronic system 300 includes a memory 310 and a memory controller 320. The memory controller 320 may control the memory 310 for data reading from the memory 310 and/or for data writing to the memory 310 in response to requests from a host 330. At least one of the memory 310 and the memory controller 320 may include the semiconductor device according to the embodiments described above with reference to FIGS. 1 to 4.

FIG. 9 is a block diagram of an electronic system including a semiconductor device according to an embodiment.

The electronic system 400 may constitute a wireless communication device, or a device capable of transmitting and/or receiving information in a wireless environment. The electronic system 400 includes a controller 410, an input/output (I/O) device 420, a memory 430, and a wireless interface 440, which are each interconnected via a bus 450.

The controller 410 may include at least one of a microprocessor, a digital signal processor, or a similar processing device. The input/output device 420 may include at least one of a keypad, a keyboard, or a display. The memory 430 may be used to store commands executed by the controller 410. For example, the memory 430 may be used to store user data. The electronic system 400 may use the wireless interface 440 to transmit/receive data via a wireless communication network. The wireless interface 440 may include an antenna and/or a wireless transceiver. In some embodiments, the electronic system 400 may be used for communication interface protocols of third-generation communication systems, such as code division multiple access (CDMA), global system for mobile communications (GSM), north American digital cellular (NADC), extended-time division multiple access (E-TDMA), and/or wide band code division multiple access (WCDMA). The electronic system 400 may include the semiconductor device according to the embodiments described above with reference to FIGS. 1 to 4.

According to the semiconductor device and the method of manufacturing the semiconductor device of the disclosure, a semiconductor device having a vertical channel may be provided, and a method of manufacturing a semiconductor device having a GAA structure using a channel last process may be provided. By using a channel last process, a method of manufacturing a semiconductor device according to example embodiments may limit and/or minimize damage to a channel during manufacturing processes for the semiconductor device. While the semiconductor devices and the semiconductor device manufacturing methods have been described with reference to the embodiments illustrated in the drawings, these are merely non-limiting examples, and it will be understood by those skilled in the art that various modifications and equivalent embodiments are possible therefrom. Therefore, the disclosed embodiments should be considered in an illustrative rather than a restrictive sense. The scope of the rights is defined by the claims, not in the foregoing disclosure, and all differences within an equivalent scope should be interpreted as being included in the scope of the rights.

According to the disclosure, a semiconductor device having a vertical channel is provided.

According to the disclosure, a method of manufacturing a semiconductor device having a GAA structure by a channel last process is provided.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a first gate electrode and a second gate electrode spaced apart from each other on a substrate;
a first channel layer on one side of the first gate electrode;
a second channel layer on one side of the second gate electrode; and
a third gate electrode connecting the first gate electrode and the second gate electrode to each other,
wherein the first channel layer and the second channel layer extend in a first direction and the first direction is perpendicular to the substrate.

2. The semiconductor device of claim 1, wherein the first channel layer is surrounded by the first gate electrode and the third gate electrode.

3. The semiconductor device of claim 1, wherein the second channel layer is surrounded by the second gate electrode and the third gate electrode.

4. The semiconductor device of claim 1, wherein
a part of the first channel layer and a part of the second channel layer extend in a second direction, and
the second direction is perpendicular to the first direction.

5. The semiconductor device of claim 1, wherein the first gate electrode, the second gate electrode, and the third gate electrode comprise TiN.

6. The semiconductor device of claim 1, wherein the first channel layer and the second channel layer each independently comprise a transition metal dichalcogenide (TMD) or an oxide semiconductor.

7. The semiconductor device of claim 6, wherein
at least one of the first channel layer and the second channel layer include the TMD, and
the TMD comprises MoS₂, WSe₂, MoSe₂, or WS₂.

8. The semiconductor device of claim 6, wherein
at least one of the first channel layer and the second channel layer include the oxide semiconductor, and
the oxide semiconductor comprises indium-gallium-zinc oxide IGZO or indium tin oxide ITO.

9. The semiconductor device of claim 1, further comprising:
a gate insulating layer surrounding the first channel layer and the second channel layer.

10. The semiconductor device of claim 9, wherein the gate insulating layer comprises a high-k material.

11. The semiconductor device of claim 10, wherein the gate insulating layer comprises at least one of aluminum oxide, hafnium oxide, zirconium oxide, or lanthanum oxide.

12. The semiconductor device of claim 1, wherein the first channel layer and the second channel layer are symmetric with respect to the third gate electrode.

13. The semiconductor device of claim 1, wherein the first channel layer and the second channel layer are not symmetric with respect to the third gate electrode.

14. A semiconductor device comprising:
a plurality of first gate electrodes spaced apart from each other in a first direction on a surface of a substrate, the first direction being perpendicular to the surface of the substrate;
a plurality of second gate electrodes on the surface of the substrate and spaced apart from each other in the first direction;
a plurality of first channel layers on one side of the plurality of first gate electrodes, respectively;
a plurality of second channel layers on one side of the plurality of second gate electrodes, respectively;
a third gate electrode connecting the plurality of first gate electrodes and the plurality of second gate electrodes to each other; and
a source electrode and a drain electrode spaced apart in a second direction on the substrate, the second direction being perpendicular to the first direction,
wherein the plurality of first channel layers and the plurality of second channel layers extend in the first direction.

15. The semiconductor device of claim 14, wherein the plurality of first gate electrodes and the plurality of second gate electrodes are spaced apart from each other in the second direction.

16. The semiconductor device of claim 14, wherein the plurality of first channel layers are surrounded by the plurality of first gate electrodes and the third gate electrode.

17. The semiconductor device of claim 14, wherein the plurality of second channel layers are surrounded by the plurality of second gate electrodes and the third gate electrode.

18. A method of manufacturing a semiconductor device comprising:
forming a plurality of gate electrodes spaced apart from each other in a first direction on a substrate, the first direction being perpendicular to the substrate;
forming a channel layer surrounding each of the plurality of gate electrodes;
etching a part of the plurality of gate electrodes to form a first gate electrode and a second gate electrode, and etching a part of the channel layer to form a first channel layer and a second channel layer;
forming a source electrode and a drain electrode spaced apart from each other on the substrate; and
forming a third gate electrode to surround the first channel layer and the second channel layer,
wherein the first channel layer and the second channel layer extend in the first direction.

19. The method of claim 18, wherein the first channel layer is formed surrounded by the first gate electrode and the third gate electrode.

20. The method of claim 18, wherein the second channel layer is formed surrounded by the second gate electrode and the third gate electrode.
